(19) United States
(12) Patent Application Publication
(10) Pub. No.: US 2009/0065146 A1
(43) Pub. Date: Mar. 12, 2009

(54) PLASMA PROCESSING APPARATUS

(75) Inventor: Jun Yamashita, Hyogo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Tokyo Electron Limited, Minato-Ku (JP)

(21) Appl. No.: 12/281,851

(22) PCT Filed: Mar. 5, 2007
(86) PCT No.: PCT/JP07/54193

§ 371 Date: Sep. 5, 2008

(30) Foreign Application Priority Data
Mar. 6, 2006 (JP) 2006-059426

(51) Int. Cl. C23F 1/08; C23C 16/513; C23C 16/511

(52) U.S. Cl. 156/345.29; 118/723 R; 118/723 AN

(57) ABSTRACT

Gas delivery ports 15 are equidistantly formed at a plurality of positions along the inner wall of the chamber 1 and are connected through gas feed passages 14 to an annular communication passage 13. The annular communication passage 13 is formed of a gap defined by step portions 18 and 19 at the junction between the upper end of a lower chamber 2 and the lower end of an upper plate 27 of a lid unit 30. The annular communication passage 13 serves as a gas distribution device for uniformly distributing and supplying gas to the gas feed passages 14. The annular communication passage 13 is connected to a gas supply source section 16 through gas passages 12 formed at arbitrary positions in the wall of the lower chamber 2 and extending in the vertical direction and gas feed ports 72.

### TECHNICAL FIELD

The present invention relates to a plasma processing apparatus, and more specifically to a plasma processing apparatus for processing a target object, such as a semiconductor substrate, by use of plasma.

### BACKGROUND ART

As a plasma processing apparatus, there is known a plasma processing apparatus of the RLSA (Radial Line Slot Antenna) type in which microwaves are supplied from a radial line slot antenna into a process chamber to generate plasma (for example, WO98/33362). A plasma processing apparatus of the RLSA type includes a cylindrical container provided with a worktable disposed therein to place a target object thereon, and an antenna member comprising a slot plate and a waveguide dielectric body to radiate microwaves. The antenna member is disposed on top of the cylindrical container with a seal member interposed therebetween to seal the junction, so that a vacuum chamber is constituted.

In order to realize an optimum process in a plasma processing apparatus of the RLSA type, it is necessary to uniformly supply a process gas for plasma generation into a vacuum chamber so as to uniformly generate plasma in the plasma generation space inside the vacuum chamber. Conventionally, as a system for supplying a process gas into a vacuum chamber, in general, a gas feed portion is formed to extend through the sidewall of the vacuum chamber and is connected to a process gas supply source located outside, so as to supply the process gas, as disclosed in Patent Document 1 quoted above, for example.

However, where a vacuum chamber has a single gas delivery port on the sidewall for supplying a process gas, the process gas can be hardly uniformly delivered into the plasma generation space inside the vacuum chamber, resulting in a difficulty in generating uniform plasma.

In order to realize uniform gas supply into a vacuum chamber, there is a system including gas delivery ports for supplying the gas at a plurality of positions on the sidewall of the vacuum chamber. In this case, a gas supply pipe needs to be disposed around the vacuum chamber, and thus requires a sufficient installation space and/or brings about restrictions of installation, such as complexity in piping to prevent interference with load and unload of a substrate. Further, in order to uniformly deliver process gases supplied at certain flow rates into a vacuum chamber, the pressure losses should be equal inside the respective process gas supply passages. However, in the case of external piping, it is difficult to equalize the lengths of gas supply pipes from the gas supply source section to corresponding gas delivery ports, thereby causing a difference between the pressure losses.

### DISCLOSURE OF INVENTION

An object of the present invention is to provide a plasma processing apparatus that can uniformly supply a process gas into a vacuum chamber and can simplify external piping.

According to the present invention, there is provided a plasma processing apparatus comprising: a process container configured to be vacuum-exhausted; a worktable configured to place a target object thereon inside the process container; a lid unit disposed on an upper side of the process container to airtightly seal the process container; and a gas feed system configured to supply a process gas for exciting plasma into the process container, wherein the gas feed system includes a process gas supply source section configured to supply the process gas, a plurality of gas delivery ports opened to a space inside the process container, a common gas communication passage connected to the plurality of gas delivery ports, and a gas channel system configured to send the process gas from the process gas supply source section through a wall of the process container into the gas communication passage.

According to the plasma processing apparatus having the structure described above, since the common gas communication passage is connected to the plurality of gas delivery ports, a process gas is uniformly distributed to the gas delivery ports and is thereby uniformly delivered from the gas delivery ports. Consequently, plasma is uniformly generated in the plasma process space inside the process container. The gas delivery ports can be set at an arbitrary height position to supply gas inside the process container in accordance with the process content. Further, since gas passages are formed through the wall of the process container to connect the process gas supply source section located outside to the gas communication passage, the external piping of the plasma processing apparatus can be simplified.

In the plasma processing apparatus described above, the gas communication passage may be a gap defined by a step portion formed on an upper end of the process container and a step portion formed on a lower end of the lid unit. Alternatively, the gas communication passage may be a gap defined by a groove formed on an upper end of the process container and a lower end surface of the lid unit. Alternatively, the gas communication passage may be a gap defined by an upper end surface of the process container and a groove formed on a lower end of the lid unit.

In this way, where a gap defined by the shapes (step portion and/or groove) of the upper end of the process container and the lower end of the lid unit, the common communication passage can be formed by a simple structure with easy machining thereof.

In the plasma processing apparatus described above, the gas channel system may include a gas supply line extending from the process gas supply source section, a plurality of gas passages formed in a wall inside the process container and connected to the gas communication passage, and a uniform gas supply mechanism configured to uniformly supply the process gas from the gas supply line to the plurality of gas passages. In this case, the uniform gas supply mechanism may include gas feed ports respectively formed at ends of the plurality of gas passages, and a plurality of gas feed pipes uniformly branched from the gas supply line and connected to the gas feed ports.

The plurality of gas feed pipes preferably have essentially the same length.

The lid unit may include an antenna configured to supply microwaves into the process container. The antenna may be a planar antenna having a plurality of slot holes formed therein.

The plasma processing apparatus is preferably arranged such that the process container includes a lower housing that surrounds the worktable and an upper housing interposed between the lower housing and the lid unit; and junctions between the lower housing and the upper housing and between the upper housing and the lid unit are respectively provided with upper and lower gas communication passages formed as the gas communication passage, and the upper and lower gas communication passages are respectively connected to a plurality of upper gas delivery ports and a plurality of lower gas delivery ports.

The plasma processing apparatus is preferably arranged such that the apparatus further comprises a plate disposed above the worktable inside the process container and having a number of through holes; and the upper gas delivery ports and the lower gas delivery ports are respectively located at height positions that interpose the plate therebetween.

In this way, where upper and lower sets of gas delivery ports are disposed with the plate interposed therebetween, gas supply positions are selected above and below the plate in accordance with the type of process gases, so that plasma is controlled to be optimum for a desired process.

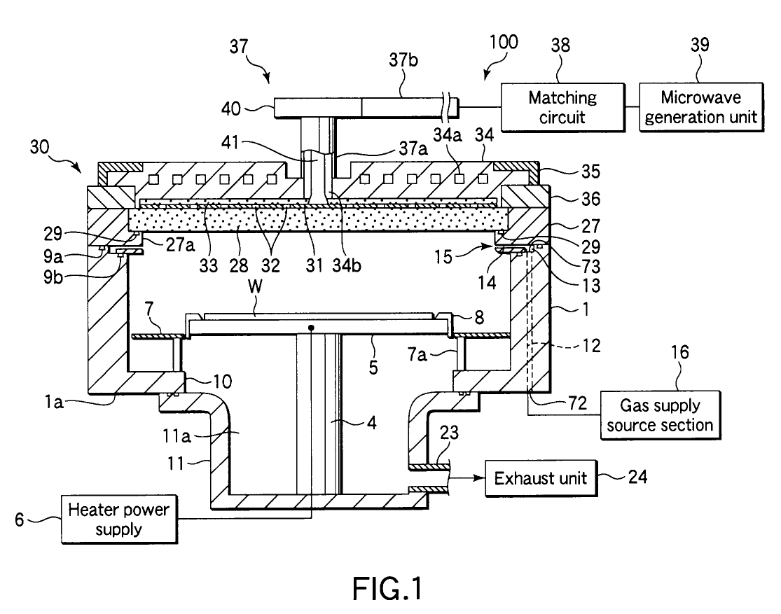

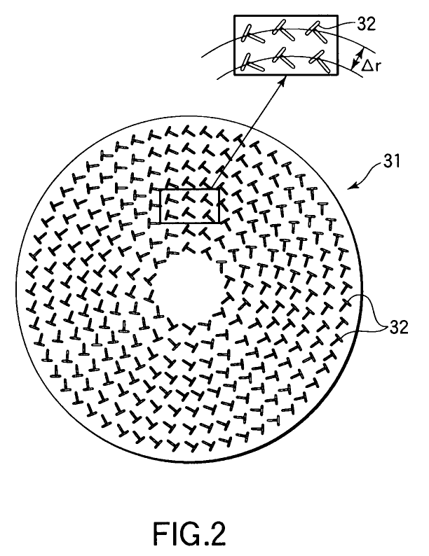

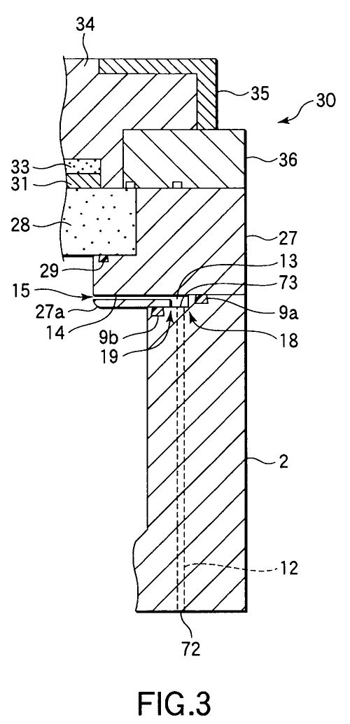

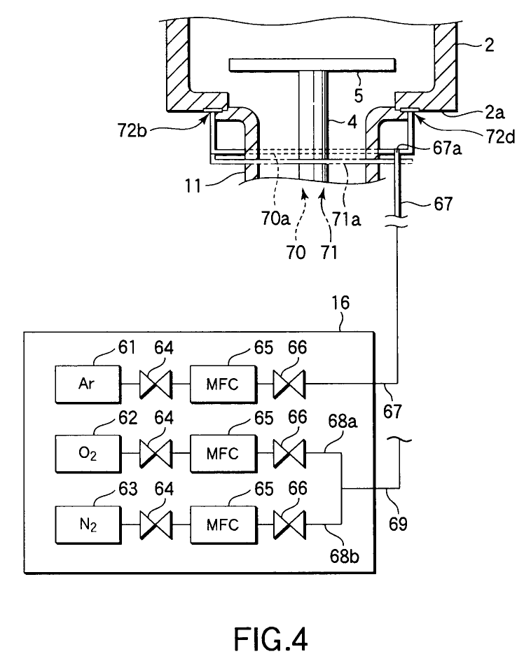

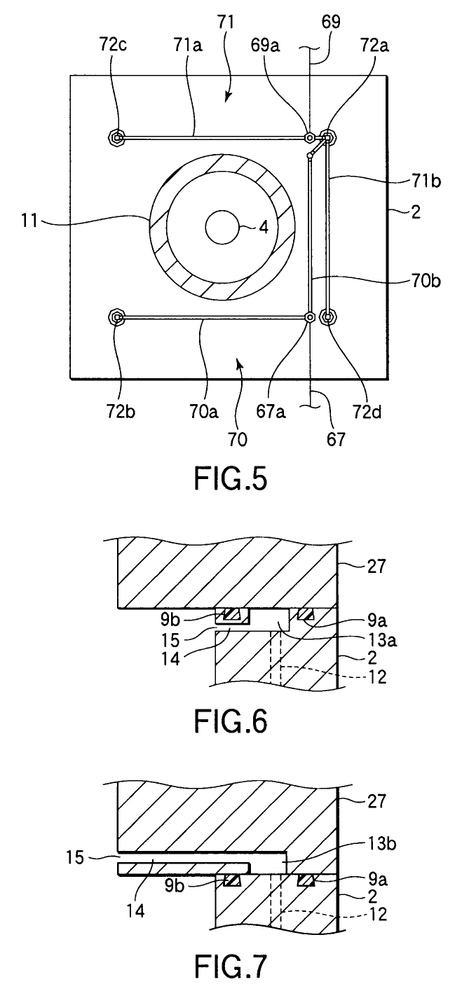

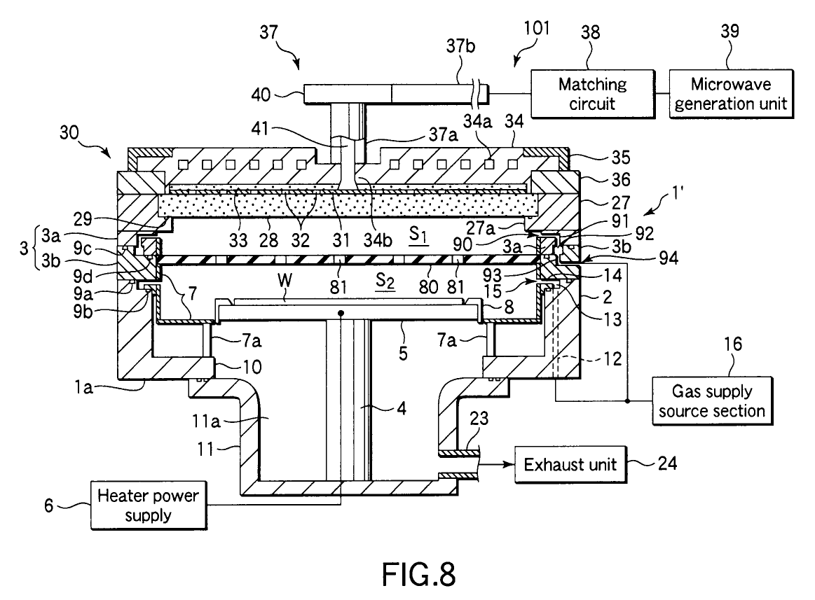

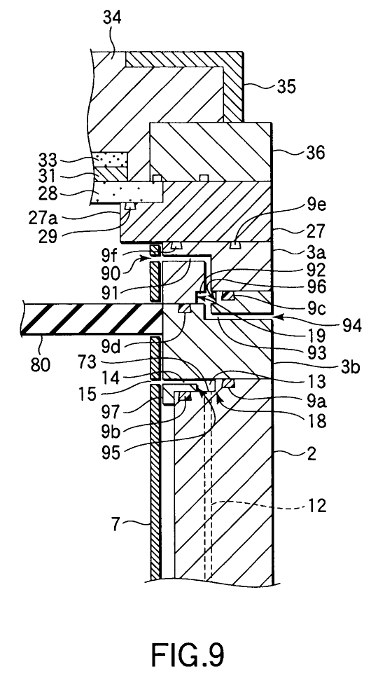

### BRIEF DESCRIPTION OF DRAWINGS

[FIG. 1] This is a sectional view schematically showing the structure of a plasma processing apparatus according to a first embodiment.

[FIG. 2] This is a plan view showing a planar antenna member.

[FIG. 3] This is an enlarged sectional view showing a main part of the apparatus shown in FIG. 1.

[FIG. 4] This is a schematic view for explaining the outline of gas supply pipes.

[FIG. 5] This is a bottom view for explaining external piping on the bottom side of a chamber.

[FIG. 6] This is a sectional view showing an alternative example of an annular communication passage.

[FIG. 7] This is a sectional view showing another alternative example of an annular communication passage.

[FIG. 8] This is a sectional view schematically showing the structure of a plasma processing apparatus according to a second embodiment.

[FIG. 9] This is an enlarged sectional view showing a main part of the apparatus shown in FIG. 8.

### BEST MODE FOR CARRYING OUT THE INVENTION

Embodiments of the present invention will now be described with reference to the accompanying drawings.

FIG. 1 is a sectional view schematically showing the structure of a plasma processing apparatus 100 according to a first embodiment of the present invention. This plasma processing apparatus 100 is arranged as a plasma processing apparatus, in which microwaves are supplied from a planar antenna having a plurality of slots, such as RLSA (Radial Line Slot Antenna), into a process chamber to generate microwave plasma with a high density and a low electron temperature.

The plasma processing apparatus 100 includes an airtight chamber 1 for accommodating a wafer W, wherein the chamber 1 has an essentially cylindrical shape and is grounded. The chamber 1 may be formed of a polygonal column with, e.g., a rectangular cross section. The chamber 1 is provided with a detachable lid unit 30 on the top, which serves to supply microwaves into the process space. In other words, the chamber 1 has an opening portion at the top, and the lid unit 30 airtightly closes this opening portion.

The lid unit 30 serves as an antenna member for supplying microwaves into the chamber 1. The antenna member 30 includes a transmission plate 28, a planar antenna member 31, and a wave-retardation body 33 laminated in this order from the susceptor 5 side. The transmission plate 28, planar antenna member 31, and wave-retardation body 33 are covered with a shield cover 34, which is made of a metal material, such as aluminum or stainless steel, and serves as a waveguide tube. The shield cover 34 is supported by an upper plate 27 through a holding ring 36. The holding ring 36 and shield cover 34 are fixed by an annular holding ring 35 having an L-shape in a cross section. A plurality of gas delivery ports 15 for supplying process gases into the chamber 1 are formed on the inner wall surface of the upper plate 27 at the bottom of the lid unit 30. The gas delivery ports 15 are connected to a gas supply source section 16 through gas feed passages. The gas feed passages of the plasma processing apparatus 100 will be explained later in detail.

The bottom wall 1a of the chamber 1 has a circular opening portion 10 formed essentially at the center. The bottom wall 1a is provided with an exhaust chamber 11 communicating with the opening portion 10 and extending downward to uniformly exhaust gas from inside the chamber 1.

A susceptor (worktable) 5 is disposed inside the chamber 1 to support a target object, such as a wafer W, thereon in a horizontal state. The susceptor 5 is made of a material, such as quartz or ceramic (AlN, Al₂O₃, etc.), and is supported by the bottom of the exhaust chamber 11. The susceptor 5 is supported by a cylindrical support member 4 extending upward from the center of the bottom of the exhaust chamber 11, and the support member 4 is supported by the exhaust chamber 11. The support member 4 and susceptor 5 are made of a ceramic material with a high thermal conductivity, such as AlN. The susceptor 5 is provided with a guide ring 8 made of, e.g., quartz and disposed on the outer edge to guide the wafer W. The susceptor 5 is further provided with a heater (not shown) of the resistance heating type embedded therein. The heater is supplied with a power from a heater power supply 6 to heat the susceptor 5, thereby heating the target object or wafer W. The temperature of the susceptor 5 is measured by a thermocouple (not shown), so that the temperature can be controlled within a range of, e.g., from room temperature to 1,000° C. An electrostatic chuck may be disposed on the susceptor 5 to electrically hold and release the wafer W.

The susceptor 5 is provided with wafer support pins (not shown) that can project and retreat relative to the surface of the susceptor 5 to support the wafer W and move it up and down. The outer periphery of the susceptor 5 is surrounded by an annular baffle plate 7 supported by a plurality of support members 7a and configured to allow gas to be uniformly exhausted from inside the chamber 1. A cylindrical liner (not shown) made of quartz is attached along the inner wall of the chamber 1 to prevent the material of the chamber from causing metal contamination, so that a clean environment is maintained.

The sidewall of the exhaust chamber 11 is connected to an exhaust unit 24 including a high speed vacuum pump through an exhaust line 23. The exhaust unit 24 can be operated to uniformly exhaust gas from inside the chamber 1 into the space 11a of the exhaust chamber 11, and then out of the exhaust chamber 11 through the exhaust line 23. Consequently, the inner pressure of the chamber 1 can be decreased at a high speed to a predetermined vacuum level, such as 0.133 Pa.

The chamber 1 has gas passages 12 formed in the sidewall and extending upward from the bottom. The gas passages 12 serve as part of the gas feed passages for supplying process gases into the chamber 1.

The chamber 1 has a transfer port provided with a gate valve for opening/closing the transfer port (they are not shown), so that the wafer W is loaded and unloaded therethrough.

The upper end of the chamber 1 is set in contact with the lower end of the upper plate 27 of the lid unit 30. Seal members 9a and 9b, such as O-rings, are disposed at the junction between the upper end of the chamber 1 and the lower end of the upper plate 27 to ensure that this junction is airtight. A step portion 18 is formed on the upper end of the chamber 1, while a step portion 19 is formed on the lower end of the upper plate 27 of the lid unit 30. The step portions 18 and 19 cooperate with each other to form an annular communication passage 13 (see FIG. 3).

The transmission plate 28 is made of a dielectric material, such as quartz, Al₂O₃, AlN, sapphire, or a ceramic, e.g., SiN. The transmission plate 28 serves as a microwave introduction window for transmitting microwaves into the process space inside the chamber 1. The bottom surface of the transmission plate 28 (on the susceptor 5 side) is not limited to a flat shape, and, for example, a recess or groove may be formed thereon to make microwaves uniform and thereby stabilize plasma. The transmission plate 28 is airtightly supported through a seal member 29 by an annular projecting portion 27a formed on the inner wall surface of the upper plate 27 below and around the lid unit 30. Accordingly, the interior of the chamber 1 can be kept airtight.

The planar antenna member 31 is formed of a circular plate and is fixed to the inner wall surface of the shield cover 34 above the transmission plate 28. For example, the planar antenna member 31 is formed of, e.g., a copper plate or aluminum plate with the surface plated with gold or silver. The planar antenna member 31 has a number of slot holes 32 formed therethrough and arrayed in a predetermined pattern, for radiating microwaves.

For example, as shown in FIG. 2, the slot holes 32 are formed of long slits. Typically, the slot holes 32 are arrayed on a plurality of concentric circles and arranged such that adjacent slot holes 32 form a T-shape. The length and array intervals of the slot holes 32 are determined in accordance with the wavelength (λg) of microwaves. For example, the intervals of the slot holes 32 are set to be λg/4, λg/2, or λg. In FIG. 2, the interval between adjacent slot holes 32 respectively on two concentric circles is expressed with Δr. The slot holes 32 may have another shape, such as through holes of a circular shape or arc shape. The array pattern of the slot holes 32 is not limited to a specific one, and, for example, it may be spiral or radial other than concentric.

The wave-retardation body 33 has a dielectric constant larger than that of vacuum, and covers the upper surface of the planar antenna member 31. For example, the wave-retardation plate 33 is made of quartz, a ceramic, a fluorocarbon resin, e.g., polytetrafluoroethylene, or a polyimide resin. Since the wavelength of microwaves becomes longer in a vacuum condition, the wave-retardation body 33 serves to shorten the wavelength of microwaves and thereby to adjust plasma. The planar antenna member 31 may be set in contact with or separated from the transmission plate 28. Similarly, the wave-retardation body 33 may be set in contact with or separated from the planar antenna member 31.

The shield cover 34 is provided with cooling water passages 34a formed therein. Cooling water is supplied to flow through the cooling water passages and thereby to cool the shield cover 34, wave-retardation body 33, planar antenna member 31, and transmission plate 28. The planar antenna member 31 and shield cover 34 are grounded through the chamber 1.

The shield cover 34 has an opening portion 34b formed at the center of the upper wall and connected to a waveguide tube 37. The waveguide tube 37 is connected to a microwave generation unit 39 at one end through a matching circuit 38. The microwave generation unit 39 generates microwaves with a frequency of, e.g., 2.45 GHz, which are transmitted through the waveguide tube 37 to the planar antenna member 31. The microwaves may have a frequency of 8.35 GHz or 1.98 GHz.

The waveguide tube 37 includes a coaxial waveguide tube 37a having a circular cross-section and extending upward from the opening portion 34b of the shield cover 34, and a rectangular waveguide tube 37b connected to the upper end of the coaxial waveguide tube 37a through a mode transducer 40 and extending in a horizontal direction. Microwaves are propagated in a TE mode through the rectangular waveguide tube 37b, and are then turned into a TEM mode by the mode transducer 40 interposed between the rectangular waveguide tube 37b and coaxial waveguide tube 37a. The coaxial waveguide tube 37a includes an inner conductive body 41 extending at the center, which is connected and fixed to the center of the planar antenna member 31 at the lower end. Consequently, microwaves are efficiently and uniformly propagated from the inner conductive body 41 of the coaxial waveguide tube 37a outward in the radial direction to the planar antenna member 31.

FIG. 3 is an enlarged view showing the structure of gas feed passages for supplying process gases into the chamber 1 in the plasma processing apparatus 100 according to this embodiment. As described above, the gas delivery ports 15 for supplying process gases into the chamber 1 are equidistantly formed along the inner wall surface of the upper plate 27 of the lid unit 30 at a plurality of positions (such as, thirty-two positions). The gas delivery ports 15 are respectively connected to gas feed passages 14 extending in the horizontal direction.

The gas feed passages 14 are connected to the annular communication passage 13, which is formed of a gap between the step portions 18 and 19 at the junction between the upper end of the chamber 1 and the lower end of the upper plate 27 of the lid unit 30. The annular communication passage 13 extends in an essentially horizontal annular direction to surround the process space. The annular communication passage 13 serves as gas distribution means for uniformly distributing and supplying a gas into the thirty-two gas feed passages 14, thereby uniformly supplying the gas to the gas delivery ports 15 without causing preferential supply to a specific one of the ports 15.

The annular communication passage 13 has feed holes 73 formed in the wall of the chamber 1 at arbitrary positions (such as, equidistant four positions). The feed holes 73 are connected to the gas supply source section 16 through gas passages 12 extending in the vertical direction (such as, two passages), gas feed ports 72, and a gas supply line 67 (or a gas supply line 69). As described above, the gas feed passages connecting the gas supply source section 16 to the respective gas delivery ports 15 are constituted by gas passages formed in the wall of the chamber, i.e., the gas passages 12, annular communication passage 13, and gas feed passages 14. In this case, the number of external piping portions can be decreased to the minimum, and passage lengths to the respective gas delivery ports 15 can be equalized without a difference in conductance. Consequently, the delivery amount of process gases from the respective gas delivery ports 15 can be controlled to be essentially uniform.

FIGS. 4 and 5 are views schematically showing the arrangement of external piping for supplying process gases into the plasma processing apparatus 100. As shown in FIG. 4, the gas supply source section 16 includes a plurality of gas sources, such as an Ar gas source 61, an O₂ gas source 62, and an N₂ gas source 63.

A gas supply line 67 extends from the Ar gas source 61 and is connected to the bottom of the chamber 1 through a uniform gas supply mechanism 70. Similarly, a gas supply line 68a extends from the O₂ gas source 62, and a gas supply line 68b extends from the N₂ gas source 63. The gas supply lines 68a and 68b converge into a gas supply line 69, which is connected to the bottom of the chamber 1 through a uniform gas supply mechanism 71. Each of the gas supply lines 67, 68a, and 68b is provided with valves 64 and 66a and a mass-flow controller interposed between the valves.

As shown in FIG. 5, the uniform gas supply mechanism 70 includes gas feed pipes 70a and 70b uniformly branched from a branching portion 67a of the gas supply line 67 and extend along the outside of the exhaust chamber 11 below the chamber 1 to form an L-shape in the plan view. The gas feed pipes 70a and 70b are connected through gas feed ports 72a and 72b formed on the lower side of the chamber 1 to two of the gas passages 12, which are respectively formed in the wall of the chamber 1 at diagonally opposite positions.

The uniform gas supply mechanism 71 includes gas feed pipes 71a and 71b uniformly branched from a branching portion 69a of the gas supply line 69 and extend along the outside of the exhaust chamber 11 below the chamber 1 to form an L-shape in the plan view. The gas feed pipes 71a and 71b are connected through gas feed ports 72c and 72d formed on the lower side of the chamber 1 to two of the gas passages 12, which are respectively formed in the wall of the chamber 1 at diagonally opposite positions.

The feed pipe 70b and feed pipe 71b are located on the same side, and the feed pipe 70a and feed pipe 71a are located opposite to each other with the exhaust chamber 11 interposed therebetween, such that the exhaust chamber 11 is surrounded by the feed pipes 70a, 70b, 71a, and 71b on three sides.

In this way, gas feed passages are divided by the feed pipes 70a and 70b branched to form an L-shape and the feed pipes 71a and 71b branched to form an L-shape below the chamber 1, so that the passage lengths from the gas supply source section 16 to the respective gas feed ports 72a to 72d are essentially equal.

As described above, according to this embodiment, gases from the gas supply source section 16 are sent through the four gas feed ports 72a to 72d and four gas passages 12 into the common annular communication passage 13, in which the gases are merged with each other and diffused. Then, the gases are distributed through the gas feed passages 14 and are uniformly delivered from the gas delivery ports 15 formed at thirty-two positions into the chamber 1, so that the process gases are uniformly supplied into the chamber 1. Consequently, plasma is uniformly excited in the plasma process space inside the chamber 1, and the process uniformity on the wafer W is thereby improved.

The gas feed ports 72a, 72b, 72c, and 72d and gas passages 12 can be located at any positions as long as they can uniformly supply gases into the chamber 1. The arrangement of the gas feed pipes 70a, 70b, 71a, and 71b is not limited to the arrangement described above, as long as the gas feed pipes 70a and 70b have essentially the same passage length and conductance as each other, and the gas feed pipes 71a and 71b have essentially the same passage length and conductance as each other.

The gas feed passages 14 connected to the gas delivery ports 15 are formed in the upper plate 27, and so the height of the upper plate 27 can be adjusted. Consequently, the gas delivery ports 15 can be set at an arbitrary height position inside the chamber 1, so that the process gases are uniformly supplied into the process space and plasma is thereby uniformly generated.

The position of the gas delivery ports 15 can be easily set in various levels in accordance with the process content, such that, for example, the gas delivery ports 15 are set to supply gas in proximity to the plasma generation area. However, where the gas delivery ports 15 are set in proximity to the plasma generation area, gas dissociation may proceed too much and/or the interior of the gas delivery ports 15 may be damaged, depending on the circumstances. In such a case, the gas delivery ports 15 can be located on a lower side.

The L-shape gas feed pipes 70a and 70b and L-shape gas feed pipes 71a and 71b, which are disposed as external piping connected to the gas feed ports 72 on the lower side of the chamber 1, are gathered below the chamber 1. This arrangement can eliminate complex piping and require only a smaller space for piping, thereby facilitating downsizing of the apparatus.

In FIG. 3, the annular communication passage 13 is formed between the step portion 18 on the upper end of the chamber 1 and the step portion 19 on the lower end of the upper plate 27. Alternatively, as shown in FIG. 6, an annular communication passage 13a may be defined by an annular groove formed on the upper end of the chamber 1 in cooperation with a flat surface on the lower end of the upper plate 27. In this case, the gas feed passages 14 and gas delivery ports 15 may be formed on the upper end surface of the chamber 1 in place of the upper plate 27.

Alternatively, as shown in FIG. 7, an annular communication passage 13b may be defined by an annular groove formed on the lower end of the upper plate 27 in cooperation with a flat surface on the upper end of the chamber 1. Further, although not shown, an annular communication passage may be defined by two annular grooves respectively formed on the upper end of the chamber 1 and the lower end of the upper plate 27, which are set in contact with each other to align the two grooves.

Next, an explanation will be given of a plasma process performed on a target object or wafer W in the plasma processing apparatus 100 having the structure described above.

At first, the wafer W is loaded into the chamber 1 and placed on the susceptor 5. Then, for example, Ar gas used as a plasma gas and O₂ gas used as an oxidizing gas are supplied at predetermined flow rates from the gas supply source section 16, through the gas supply lines 67 and 69, feed pipes 70a, 70b, 71a, and 71b, gas feed ports 72, gas passages 12, and annular communication passage 13, and further through the gas feed passages 14 and gas delivery ports 15 formed at thirty-two positions, into the chamber 1. For example, process conditions used at this time are as follows.

Ar gas flow rate: 1,000 mL/min (sccm),

O₂ gas flow rate: 10 mL/min (sccm),

Pressure: 133 Pa (1 Torr), and

Process temperature: 500° C.

Then, microwaves are supplied from the microwave generation unit 39 through the matching circuit 38 into the waveguide tube 37. The microwaves are guided through the rectangular waveguide tube 37b, mode transducer 40, and coaxial waveguide tube 37a in this order, and are then propagated through the inner conductive body 41 to the planar antenna member 31. Then, the microwaves are radiated from the slots of the planar antenna member 31 through the transmission plate 28 into the chamber 1.

The microwaves are propagated in a TE mode through the rectangular waveguide tube 37b, and are then turned from the TE mode into a TEM mode by the mode transducer 40 and propagated in the TEM mode through the coaxial waveguide tube 37a to the planar antenna member 31. When the microwaves are radiated from the planar antenna member 31 through the transmission plate 28 into the chamber 1, an electromagnetic field is thereby formed inside the chamber 1 and turns the process gases into plasma. With this plasma, a predetermined process, such as an oxidation process in the case of the Ar gas and O₂ gas used in this example, is preformed on the wafer W.

Since microwaves are radiated from a number of slot holes 32 of the planar antenna member 31, this plasma has a high plasma density of about 1×10¹⁰ to 5×10¹²/cm³ and a low electron temperature of 2 eV or less. Particularly, this plasma has a low electron temperature of about 1.5 eV or less near the wafer W. Accordingly, where this plasma acts on the wafer W, the process can be performed while suppressing plasma damage.

Next, an explanation will be given of a second embodiment of the present invention.

FIG. 8 is a sectional view schematically showing the structure of a plasma processing apparatus 101 according to the second embodiment. FIG. 9 is a sectional view showing a main part of the plasma processing apparatus 101. In the plasma processing apparatus 101 shown in FIGS. 8 and 9 according to the second embodiment, the constituent elements having substantially the same function and arrangement as those of the plasma processing apparatus 100 shown in FIG. 1 according to the first embodiment are denoted by the same reference numerals, and their explanation will be omitted.

The plasma processing apparatus 101 is formed of a chamber 1′ and a lid unit 30, wherein the chamber 1′ includes a lower chamber 2 and an upper chamber 3 disposed on top of the lower chamber 2. The upper chamber 3 is formed of a first sidewall member 3a and a second sidewall member 3b. A shower plate 80 having a number of through holes 81 formed therein is disposed in the plasma process space inside the chamber 1′. The shower plate 80 is fixed to the wall of the second sidewall member 3b of the upper chamber 3 by a stopper device (not shown). The shower plate 80 may be fixed to the wall of the first sidewall member 3a or lower chamber 2. The plasma process space is divided by the shower plate 80 into an upper space S₁ and a lower space S₂, which communicate with each other through the through holes 81.

As in the first embodiment, gas delivery ports 15 are formed along the inner wall surface of the lower chamber 2 facing the lower space S₂ at a plurality of positions (such as, thirty-two positions). The gas delivery ports 15 are connected respectively through gas feed passages 14 to an annular communication passage 13 formed essentially in the horizontal direction, which is connected to a plurality of (such as, four) gas passages 12 formed essentially in the vertical direction in the lower chamber 2. The gas passages 12 are connected to a gas supply source section 16, so that O₂ gas used as a reaction gas is supplied from an O₂ gas source (not shown) into the chamber 1′.

Further, gas delivery ports 90 are formed along the inner wall surface of the first sidewall member 3a of the upper chamber 3 facing the upper space S₁ at a plurality of positions, such as thirty-two positions. The gas delivery ports 90 are connected respectively through gas feed passages 91 to an annular communication passage 92 formed essentially in the horizontal direction, which is connected to a plurality of (such as, four) gas passages 93 formed in the second sidewall member 3b. The gas passages 93 are connected through gas feed ports 94 to the gas supply source section 16, so that Ar gas used as a plasma gas is supplied from an plasma gas source (not shown) into the chamber 1′.

A step portion 95 is formed on the lower side of the second sidewall member 3b of the upper chamber 3, while a step portion 18 is formed on the upper side of the lower chamber 2. The step portions 95 and 18 cooperate with each other to form an annular communication passage 33. Further, a step portion 96 is formed on the upper side of the second sidewall member 3b, while a step portion 19 is formed on the lower side of the first sidewall member 3a. The step portions 96 and 19 cooperate with each other to form an annular communication passage 92.

Seal members 9a and 9b, such as O-rings, are disposed at the junction between the upper end of the lower chamber 2 and the lower end of the second sidewall member 3b of the upper chamber 3 to ensure that this junction is airtight. Similarly, seal members 9c and 9d, such as O-rings, are disposed at the junction between the upper end of the second sidewall member 3b and the lower end of the first sidewall member 3a to ensure that this junction is airtight.

Furthermore, seal members 9e and 9f, such as O-rings, are disposed at the junction between the upper end of the first sidewall member 3a and the lower end of the upper plate 27 of the lid unit 30 to ensure that this junction is airtight.

The second sidewall member 3b has an annular projecting portion 97 formed at the lower end along the inner wall surface and extending vertically downward like a cover (or skirt). The projecting portion 97 covers the interface (or junction) between the second sidewall member 3b and lower chamber 2 to prevent plasma from directly acting on the seal member 9b, such as an O-ring, and thereby bringing about plasma damage thereon. The seal member 9b is made of a material that can be easily deteriorated when exposed to plasma, such as a fluorocarbon rubber material (for example, Chemraz (TM: Greene, Tweed & Co. Ltd.) and Viton (TM: DuPont Dow Elastomers LLC).

In the plasma processing apparatus 101 according to this embodiment, the chamber 1′ is provided with the shower plate 80 therein, and the gas delivery ports 90 for supplying a first process gas into the upper space S₁ and the gas delivery ports 15 for supplying a second process gas into the lower space S₂ are separately formed. In this case, for example, while Ar gas for generating plasma is supplied into the upper space S₁, a reaction gas, such as O₂ gas for an oxidizing reaction, can be supplied into the lower space S₂. Consequently, for example, dissociation of the reaction gas supplied into the lower space S₂ can be minimized, so that plasma is controlled to be optimum for an oxidation process or the like.

The present invention is not limited to the embodiments described above, and it may be modified in various manners. For example, in the embodiments described above, the plasma processing apparatus 100 is exemplified by the RLSA type, but the plasma processing apparatus may be of another type, such as the remote plasma type, ICP type, ECR type, surface reflection wave type, or magnetron type

In the embodiments described above, the plasma processing apparatuses 100 and 101 have the cylindrical chamber 1 for processing a semiconductor wafer formed of a circular plate. Alternatively, for example, a divisible structure according to the present invention may be applied to a plasma processing apparatus including a chamber having a rectangular shape in a horizontal cross section for processing a rectangular FPD glass substrate.

The type of gases supplied from the gas supply source section 16 is not limited to those described above. For example, the gas supply source section 16 may be arranged to supply other process gases at predetermined flow rates, which are exemplified by a rare gas, such as Kr or He; an oxidizing gas, such as N₂O, NO, NO₂, or CO₂; a nitriding gas, such as NH₃; film formation gases for depositing an oxide film, such as SiH₄ and O₂; film formation gases for depositing a nitride film, such as SiH₄ and N₂; film formation gases for depositing a Low-k film (low dielectric constant film), such as TMA (trimethylamine) and O₂; and/or etching gas, such as C₄F₈, C₅F₆, BCl₃, HBr, or HCl. By use of such process gases, the apparatus is structured to perform a predetermined process, such as an oxidation process, nitridation process, oxynitridation process, deposition process, or etching process.

### INDUSTRIAL APPLICABILITY

The present invention is generally applicable to plasma processing apparatuses for performing a plasma process on a target object while supplying a process gas into a process container.

1. A plasma processing apparatus comprising:
a process container configured to be vacuum-exhausted;
a worktable configured to place a target object thereon inside the process container;
a lid unit disposed on an upper side of the process container to airtightly seal the process container; and
a gas feed system configured to supply a process gas for exciting plasma into the process container,
wherein the gas feed system includes
a process gas supply source section configured to supply the process gas,
a plurality of gas delivery ports opened to a space inside the process container,
a common gas communication passage connected to the plurality of gas delivery ports, and
a gas channel system configured to send the process gas from the process gas supply source section through a wall of the process container into the gas communication passage.

2. The plasma processing apparatus according to claim 1, wherein the gas communication passage is a gap defined by a step portion formed on an upper end of the process container and a step portion formed on a lower end of the lid unit.

3. The plasma processing apparatus according to claim 1, wherein the gas communication passage is a gap defined by a groove formed on an upper end of the process container and a lower end surface of the lid unit.

4. The plasma processing apparatus according to claim 1, wherein the gas communication passage is a gap defined by an upper end surface of the process container and a groove formed on a lower end of the lid unit.

5. The plasma processing apparatus according to claim 1, wherein the gas channel system includes a gas supply line extending from the process gas supply source section, a plurality of gas passages formed in a wall inside the process container and connected to the gas communication passage, and a uniform gas supply mechanism configured to uniformly supply the process gas from the gas supply line to the plurality of gas passages.

6. The plasma processing apparatus according to claim 5, wherein the uniform gas supply mechanism includes gas feed ports respectively formed at ends of the plurality of gas passages, and a plurality of gas feed pipes uniformly branched from the gas supply line and connected to the gas feed ports.

7. The plasma processing apparatus according to claim 6, wherein the plurality of gas feed pipes have essentially the same length.

8. The plasma processing apparatus according to claim 1, wherein the lid unit includes an antenna configured to supply microwaves into the process container.

9. The plasma processing apparatus according to claim 8, wherein the antenna is a planar antenna having a plurality of slot holes formed therein.

10. The plasma processing apparatus according to claim 1, wherein the process container includes a lower housing that surrounds the worktable and an upper housing interposed between the lower housing and the lid unit; and
junctions between the lower housing and the upper housing and between the upper housing and the lid unit are respectively provided with upper and lower gas communication passages formed as the gas communication passage, and the upper and lower gas communication passages are respectively connected to a plurality of upper gas delivery ports and a plurality of lower gas delivery ports.

11. The plasma processing apparatus according to claim 10, wherein the apparatus further comprises a plate disposed above the worktable inside the process container and having a number of through holes; and
the upper gas delivery ports and the lower gas delivery ports are respectively located at height positions that interpose the plate therebetween.
